(19) United States
(12) Patent Application Publication
(10) Pub. No.: US 2010/0237469 A1
(43) Pub. Date: Sep. 23, 2010

(54) PHOTOMASK, SEMICONDUCTOR DEVICE, AND CHARGED BEAM WRITING APPARATUS

(76) Inventors: Masato SAITO, Tokyo (JP); Hidehiro WATANABE, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/726,052

(22) Filed: Mar. 17, 2010

(30) Foreign Application Priority Data
Mar. 23, 2009 (JP) 2009-071009
Feb. 24, 2010 (JP) 2010-038573

(51) Int. Cl. H01L 23/544; H01J 37/317; H01J 37/147; H01J 37/302; G06F 17/50

(52) U.S. Cl. 257/618; 250/396 R; 250/492.22; 716/19; 257/E23.179

(57) ABSTRACT

A photomask has a pattern formed by writing of a charged beam on basis of a charged beam control data. The charged beam control data is produced by: setting a plurality of correction points in a writing area on pattern data; performing a simulation of writing with a charged beam on basis of the pattern data to divide the writing area, at time of writing each of the correction points, into a written area of writing been already completed and an unwritten area of writing yet to be performed; deriving, for each of the correction points, a first charging amount distribution due to a fogging effect around each of the correction points using a subset of the pattern data belonging to the written area; deriving, for each of the correction points, a second charging amount distribution modified from the first charging amount distribution on basis of an effect by which the charging amount due to the fogging effect is reduced at a position irradiated with the charged beam; deriving amount of pattern displacement at each of the correction points on basis of the second charging amount distribution; and deriving correction parameters of pattern position on basis of the amount of pattern displacement.

### CROSS-REFERENCE TO RELATED APPLICATIONS

This application is based upon and claims the benefit of priority from the prior Japanese Patent Application No. 2009-071009, filed on Mar. 23, 2009 and the prior Japanese Patent Application No. 2010-038573, filed on Feb. 24, 2010; the entire contents of which are incorporated herein by reference.

### BACKGROUND OF THE INVENTION

This invention relates to a photomask, a semiconductor device, and a charged beam writing apparatus.

A patterning method primarily based on an electron beam lithography system is widely used to manufacture a photomask, which is used as the master of a semiconductor circuit pattern in manufacturing a semiconductor device. In this patterning method, a substrate with the surface coated with a resist is held on a writing stage in the lithography system. While moving the stage, the substrate is irradiated with an electron beam to accumulate energy in the resist. Subsequently, the substrate is subjected to such processing as development and etching to form a pattern corresponding to the accumulated energy on the substrate.

Semiconductor device pattern data can be previously produced and inputted to the lithography system, and the lithography system can perform stage motion control and beam irradiation control in accordance therewith so that a desired device pattern can be formed on the substrate.

A charged beam irradiation position is controlled by a deflector incorporated in the lithography system. Typically, the deflection area controllable by the deflector is smaller than the substrate size and hence is combined with the motion of the substrate holding stage to enable writing to the entire substrate surface.

The writing method for writing to the entire substrate surface while sequentially or continuously moving the deflection area has the problem of degradation in pattern position accuracy due to charging of the resist.

Recently, requirements for pattern position accuracy on the photomask have become more demanding, and the amount of degradation in pattern position accuracy due to resist charge-up has become non-negligible. In this context, a method for improving the pattern position accuracy is proposed. In this method, pattern displacement due to resist charge-up is previously predicted from pattern data inputted to the lithography system, and writing correction parameters for correcting the predicted pattern displacement are produced. Writing is performed using these correction parameters to improve the pattern position accuracy.

However, the detailed principles of the resist charge-up phenomenon have yet to be elucidated, and the correction relies on the approximation devised on the basis of its own models. Hence, in the existing correction approaches, the correction accuracy varies with extrinsic factors such as difference in resist species and difference in the lithography systems. In other words, the correction simply relying on the writing pattern data alone cannot provide sufficient correction accuracy. Thus, a correction method with higher accuracy is desired.

In the method proposed in JP-A 2002-158167 (Kokai), preliminary exposure for locally irradiating the exposure surface with a charged particle beam is performed to obtain the potential distribution on the exposure surface. On the basis of this surface potential distribution, an electromagnetic equation of motion is solved to determine the trajectory shift of the charged particle beam due to charging of the exposure surface. Then, this trajectory shift is used to correct the deflection angle of the charged particle beam. However, in this method, to obtain the potential distribution, measurements are made by actually performing exposure, which requires substantial time and effort.

### SUMMARY OF THE INVENTION

According to an aspect of the invention, there is provided a photomask having a pattern formed by writing of a charged beam on basis of a charged beam control data, the charged beam control data being produced by: setting a plurality of correction points in a writing area on pattern data; performing a simulation of writing with a charged beam on basis of the pattern data to divide the writing area, at time of writing each of the correction points, into a written area of writing been already completed and an unwritten area of writing yet to be performed; deriving, for each of the correction points, a first charging amount distribution due to a fogging effect around each of the correction points using a subset of the pattern data belonging to the written area; deriving, for each of the correction points, a second charging amount distribution modified from the first charging amount distribution on basis of an effect by which the charging amount due to the fogging effect is reduced at a position irradiated with the charged beam; deriving amount of pattern displacement at each of the correction points on basis of the second charging amount distribution; and deriving correction parameters of pattern position on basis of the amount of pattern displacement.

According to another aspect of the invention, there is provided a semiconductor device having a device pattern corresponding to the pattern formed on the above photomask, the device pattern being formed using the photomask.

According to still another aspect of the invention, there is provided a charged beam writing apparatus, including: an input device used to input writing pattern data; a processor configured to perform a simulation of writing with a charged beam on basis of the pattern data to divide a writing area, at time of writing each of a plurality of correction points set in the writing area on the pattern data, into a written area of writing been already completed and an unwritten area of writing yet to be performed; to derive, for each of the correction points, a first charging amount distribution due to a fogging effect around each of the correction points using a subset of the pattern data belonging to the written area; to derive, for each of the correction points, a second charging amount distribution modified from the first charging amount distribution on basis of an effect by which the charging amount due to the fogging effect is reduced at a position irradiated with the charged beam; to derive amount of pattern displacement at each of the correction points on basis of the second charging amount distribution; and to derive correction parameters of pattern position on basis of the amount of pattern displacement; a charged beam source; and a deflector controllably deflecting a charged beam from the charged beam source on basis of the correction parameters of pattern position.

### BRIEF DESCRIPTION OF THE DRAWINGS

FIG. 1A shows an example pattern written to a resist formed on a substrate, and FIG. 1B is a schematic view showing displacements of the irradiation trajectory of charged beam due to charging of a resist;

FIG. 2 is a block diagram illustrating the configuration of an apparatus for producing charged beam control data according to an embodiment;

FIG. 3 is a flow chart of a method for producing charged beam control data according to the embodiment;

FIGS. 4A and 4B are schematic views showing a writing area based on writing pattern data in the embodiment;

FIGS. 5A to 5E show an example of each function used in the embodiment;

FIG. 6 is a schematic view of a charged beam writing apparatus according to the embodiment; and

FIGS. 7A to 7C are schematic cross-section views showing a method for manufacturing a semiconductor device according to the embodiment.

### DETAILED DESCRIPTION

An embodiment will be described with reference to the case of writing a desired pattern to a resist formed on a substrate while irradiating the resist with an electron beam, taken as an example of the charged beam.

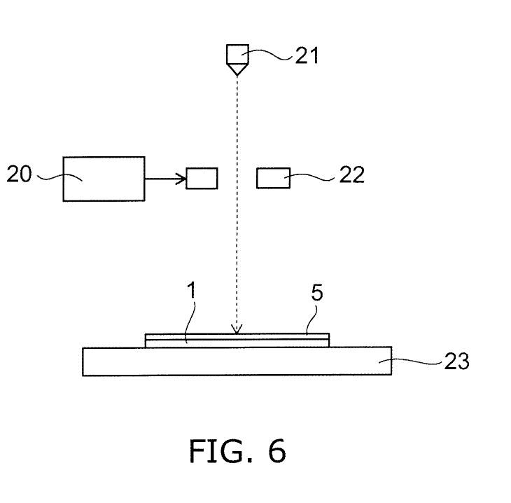

FIG. 6 is a schematic view of a charged beam writing apparatus according to the embodiment.

The writing apparatus includes an electron gun 21 as a charged beam source, deflector 22, stage 23 holding a mask substrate 1, and an apparatus 20 for producing charged beam control data.

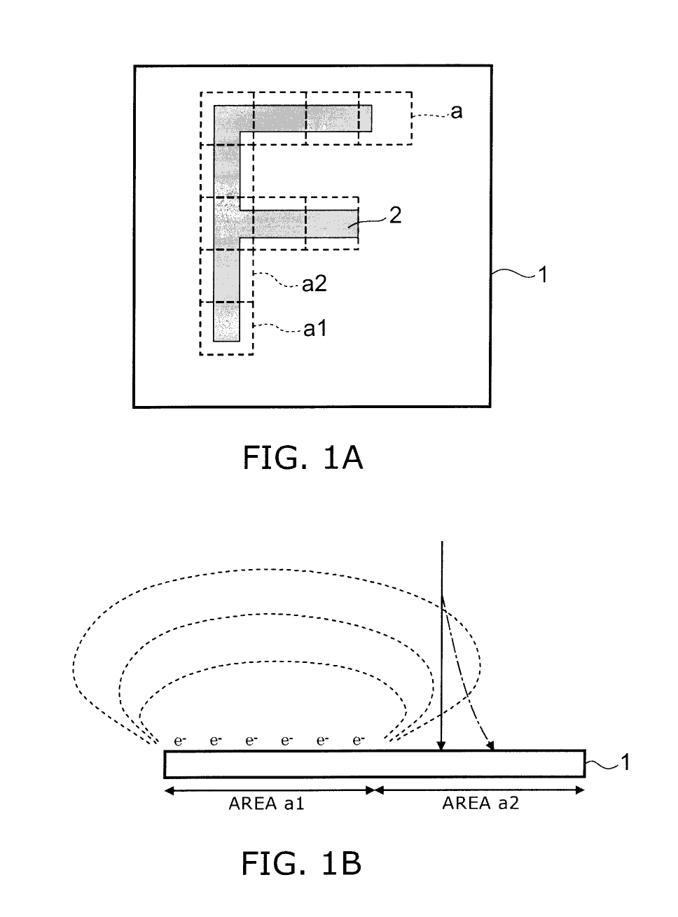

FIG. 1A shows an example pattern 2 written to a resist formed on a substrate 1. The writing area of the pattern 2 is partitioned into a plurality of areas a (indicated by dotted lines), which are within the deflectable range of the charged beam.

For instance, the position of the stage 23 holding the substrate 1 is set so that the area a1 lies within the deflectable range of the charged beam, and then the pattern in the area a1 is written with the charged beam irradiation position controlled by the deflector 22 of the lithography system. Next, the stage 23 is moved so that the area a2 lies within the deflectable range of the charged beam, and the pattern in the area a2 is written with the charged beam irradiation position controlled by the deflector 22. Such operation is repeated for each area a to write the desired pattern 2.

This may be performed by the “step-and-repeat process” in which for each irradiation of the area a, the stage 23 is moved and then paused for pattern writing in the target area a, and subsequently the stage 23 is moved to the next writing area. Alternatively, it may be performed by the process of “continuous stage motion” in which each area a is continuously tracked and subjected to writing operation without stopping the stage 23.

The process for writing to the entire substrate surface while sequentially or continuously moving the deflectable area of the charged beam has the problem of degradation in pattern position accuracy due to charging of the resist 5.

FIG. 1B shows a cross section of the two adjacent areas a1 and a2 in FIG. 1A. Here, it is assumed that writing with the charged beam has already been performed on the area a1 but has not yet been performed on the area a2.

A resist made of a resin-based material is typically a nonconductor. Hence, the resist in the area a1 already irradiated with the charge beam (electron beam) is charged and generates an electric field (schematically indicated by dotted lines) in the surrounding area. The effect of this electric field reaches the area a2, which is an adjacent unwritten area. Thus, the originally desired trajectory (solid line) of the electron beam subsequently incident on the area a2 for writing to the area a2 is distorted like the trajectory indicated by the dot-dashed line by the electric field generated by the charging of the area a1. Consequently, the position of the resulting pattern is shifted, and the pattern position accuracy is degraded.

As a result of studies on the resist charging phenomenon, the inventors have concluded that the charges charged on the resist are primarily attributed to scattered electrons resulting from the fogging phenomenon and that the electrons injected for patterning presumably serve to reduce the amount of charges charged by the fogging phenomenon.

The fogging phenomenon is a phenomenon in which incident electrons scattered by Coulomb repulsion at the sample surface are reflected or scattered by structures (electromagnetic lens etc.) around the sample surface and injected again into the sample.

Hence, in order to correct the pattern displacement due to resist charge-up, it is effective to determine the charging amount distribution around the correction position by taking into consideration the charging of the resist due to the fogging effect and the reduction of the charging amount due to injected charges and calculate the amount of pattern displacement at the correction position on the basis of this charging amount distribution.

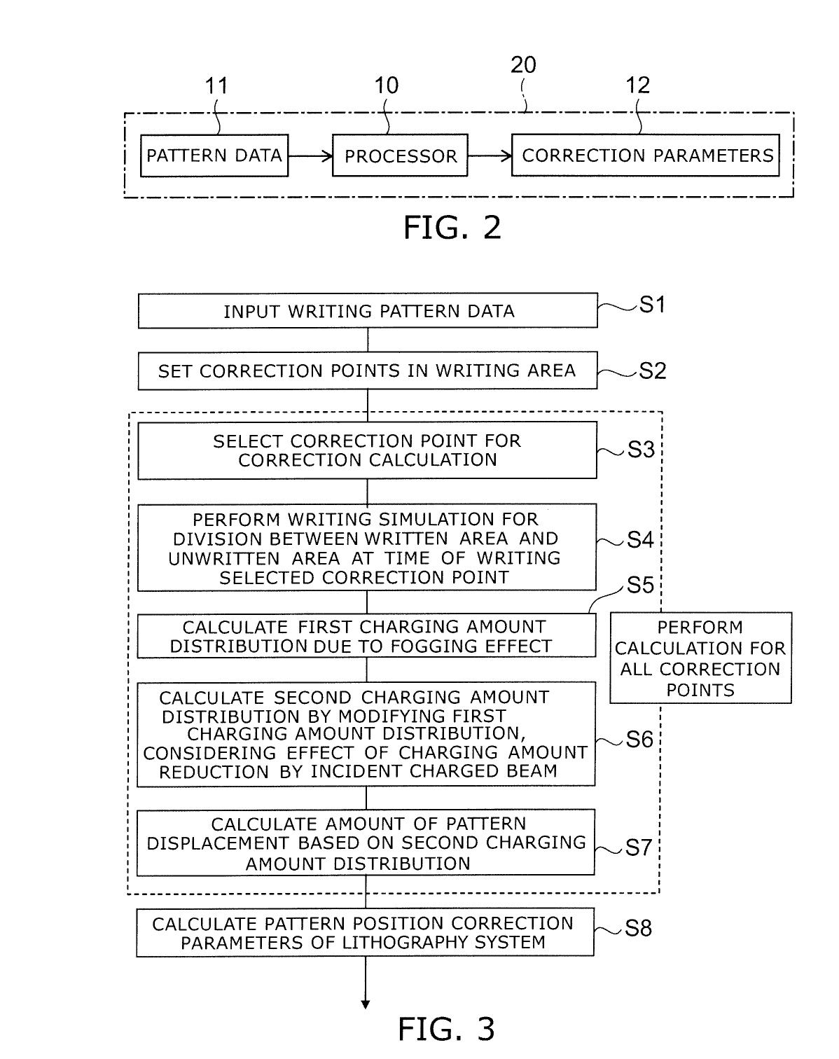

FIG. 2 is a block diagram illustrating the configuration of an apparatus 20 for producing charged beam control data according to this embodiment. The apparatus 20 for producing charged beam control data according to this embodiment includes an input device 11 used to input writing pattern data, a processor 10 for performing various processes including arithmetic operation, and an output device 12 for outputting the processed result, such as correction parameters described later, obtained by the processes by the processor 10.

This apparatus 20 for producing charged beam control data may be separate from the lithography system or the control system (such as a high-voltage power supply system for accelerating the charged beam, a beam control system for controllably deflecting the charged beam, and a stage control system) of the lithography system. Alternatively, it may be incorporated in the lithography system, or the control system of the lithography system may double as the apparatus for producing charged beam control data according to this embodiment. If the control system of the lithography system is configured to serve for production of charged beam control data according to this embodiment, correction parameters can be calculated by an in-line process in a series of writing processes. The format of the calculated correction parameters and the method for importing the correction parameters into the lithography system can be adapted to individual systems.

The processor 10 performs a series of processes described below on the basis of the writing pattern data inputted via the input device 11. In this series of processes, the processor 10 reads a program for producing charged beam control data according to this embodiment and performs the series of processes under the instructions of the program.

FIG. 3 is a flow chart of a method for producing charged beam control data according to this embodiment.

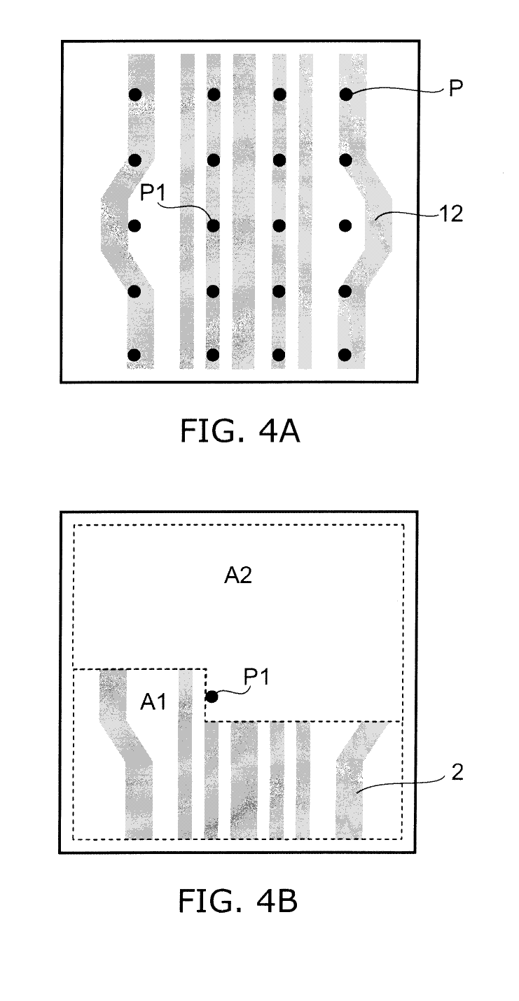

First, writing pattern data is loaded into the processor 10 via the aforementioned input device 11 (step S1). In this embodiment, writing of the pattern 2 shown in FIG. 4A is taken as an example.

Next, as shown in FIG. 4A, a plurality of correction points P (indicated by bullets) are set in the writing area on the pattern data (step S2). In the example shown in FIG. 4A, a plurality of correction points P are set as equally spaced grid points.

Next, an arbitrary point of the plurality of correction points P is selected (step S3). Here, for instance, it is assumed that the correction point P1 is selected.

Next, writing with a charged beam is simulated on the basis of the pattern data so that, at the time of writing the correction point P1, a written area A1, where writing has already been completed, and an unwritten area A2, where writing has yet to be performed, are divided as shown in FIG. 4B (step S4).

When the pattern 2 is actually written, a writing sequence representing the order of writing has been configured. Here, on the basis of the configured writing sequence, at the time of writing the correction point P1, the written area A1, where writing has already been completed, and the unwritten area A2, where writing has yet to be performed, are determined.

Next, a first charging amount distribution due to the fogging effect around the correction point P1 is calculated (step S5). Here, only the pattern data belonging to the written area A1 resulting from the division in the aforementioned step S4 is used as the pattern data to calculate the charging amount distribution.

Various methods for estimating the charging amount on the resist surface resulting from the fogging effect have been proposed in order to modulate the amount of charged beam irradiation to correct the pattern dimension affected by resist exposure due to the fogging effect, and similar methods can be used herein.

In this embodiment, assuming that the scattering distribution of the incident beam is Gaussian, the first charging amount distribution function F1(x) resulting from the fogging effect can be expressed as

F1(x)=(α/πσf²)∫∫D(x′)exp(−(x−x′)2/σf²)dx′

where σf is the influence radius of the fogging effect, D(x′) is the irradiation amount distribution function (distribution function of pattern coverage) of the electron beam on the sample (resist), which is derived from the aforementioned pattern data belonging to the written area A1, and α is an arbitrary coefficient.

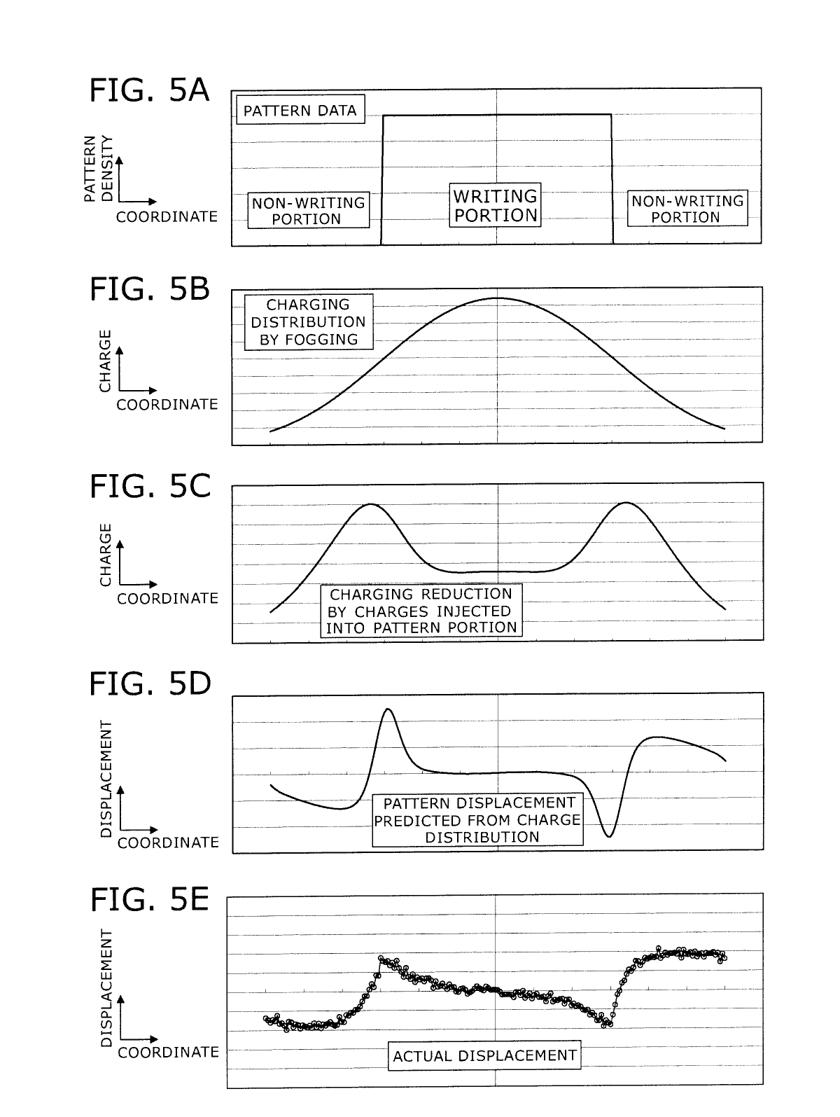

That is, for D(x′) as shown in FIG. 5A, its convolution with a Gaussian yields a first charging amount distribution function F1(x) resulting from the fogging effect as shown in FIG. 5B.

Next, on the basis of the effect by which the charging amount resulting from the fogging effect is reduced at the position irradiated with the charged beam, the aforementioned first charging amount distribution function F1(x) is modified to calculate a second charging amount distribution function F2(x) (step S6).

More specifically, at the position irradiated with the charged beam (electron beam), the injected electron may cause the charge charged by the fogging effect to migrate, such as dissipate to below the resist film, thereby reducing the charging amount (amount of charges). By taking this effect into consideration, a charging amount distribution further fitted to actual measurements can be determined.

The second charging amount distribution function F2(x), modified from F1(x), can be expressed as

F2(x)=F1(x)·∫∫D(x′)fr(x−x′)dx′

where fr(x) is the function representing the reduction of the charging amount due to charged beam irradiation. An example of F2(x) is shown in FIG. 5C.

Next, the second charging amount distribution function F2(x) is used to calculate the amount of pattern displacement at the correction point P1 (step S7). Here, the amount of pattern displacement represents the amount of deviation of the charged beam irradiation position from the original (preset) charged beam irradiation position due to the effect of the electric field generated by resist charge-up.

In this embodiment, the amount of pattern displacement is determined by convolution of the preset conversion function with the second charging amount distribution function F2(x).

The amount of pattern displacement, ΔPos(x), at the correction point P1 can be expressed as

ΔPos(x)=γ∫∫F2(x′)fc(x−x′)dx′

where fc(x) is the conversion function for converting the second charging amount distribution function F2(x) to the amount of pattern displacement, and γ is an arbitrary coefficient.

An example of the amount of pattern displacement, ΔPos(x), is shown in FIG. 5D. This indicates that the irradiation position of the charged beam is displaced in opposite directions on both sides across the peak position of the amount of charges. As compared with the actual displacement distribution shown in FIG. 5E, it can be seen that the calculated distribution has nearly the same tendency.

Determining the amount of pattern displacement, ΔPos(x), by convolution of the conversion function fc(x) with the second charging amount distribution function F2(x) simplifies calculation, reduces calculation time, and allows a less powerful computer (processor) to perform calculation, as compared with its determination based on trajectory simulation of the charged beam.

The aforementioned process from step S3 to step S7 is performed for all the correction points P to calculate the amount of pattern displacement at respective correction points P. Then, the amount of pattern displacement for all the correction points P is used to calculate correction parameters of the pattern position (step S8).

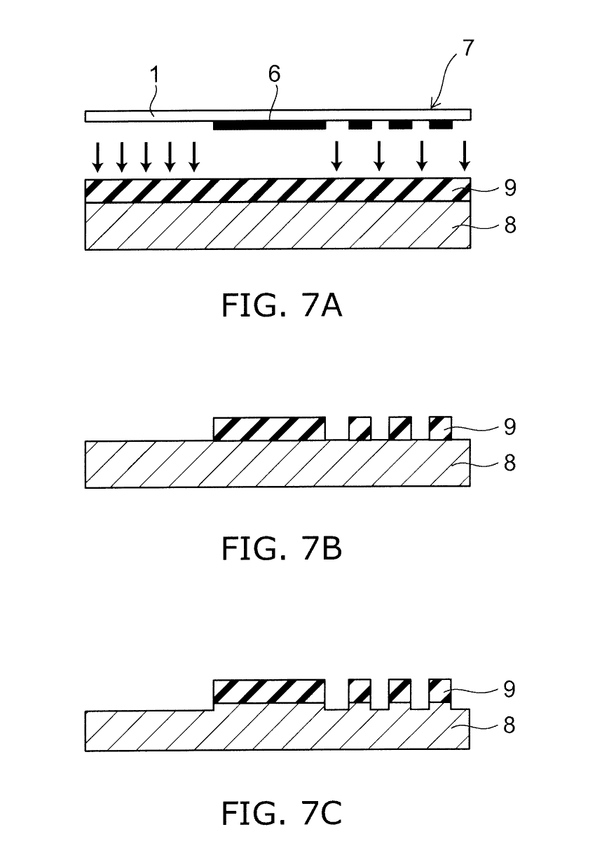

The correction parameters obtained by the foregoing process are inputted to the writing apparatus shown in FIG. 6 and used to correct the initialization values of charged beam control data. The corrected control data is used for deflection control of the charged beam to perform writing. This enables manufacturing of a photomask with high accuracy in which the pattern displacement due to resist charge-up is eliminated. After pattern writing, as shown in FIG. 7A, development is performed to form the desired pattern (shading film or halftone film) 6 on the mask substrate 1.

Then, as shown in FIG. 7A, this photomask 7 is used to perform exposure on a semiconductor wafer 8 with a resist 9 formed thereon so that a pattern image is transferred to the resist 9. Subsequently, as shown in FIG. 7B, development is performed to pattern the resist 9, and, as shown in FIG. 7C, the resist pattern 9 is used as a mask to perform processes such as etching of a film to be processed. Thus, the device pattern corresponding to the pattern 6 formed on the photomask 7, is formed on the semiconductor device. According to this embodiment, the mask pattern accuracy can be enhanced. Consequently, it is possible to increase processing accuracy of the wafer and manufacture products with high quality.

Furthermore, what is performed in this embodiment is not to obtain the charging amount distribution by measuring the charging amount after actually performing pattern writing with a charged beam, but to predict the charging amount distribution by simulation based on the inputted pattern data. Hence, it is efficient and cost-effective.

It is noted that the amount of pattern displacement may be determined by individually simulating the charged beam irradiation trajectory from the second charging amount distribution function F2(x) on the basis of electromagnetics, taking the structure of the lithography system and the like into consideration. In this case, the amount of pattern displacement can be determined with high accuracy.

Alternatively, the amount of pattern displacement may be determined by using a distribution obtained by differentiating the second charging amount distribution, and a preset conversion function.

Also in this case, the process up to step S6 is performed as in the aforementioned method to calculate the second charging amount distribution function F2(x).

Next, a third distribution function F3(x) is derived by differentiating F2(x).

F3(x) is expressed as F3(x)=dF2(x)/dx.

Next, the third distribution function F3(x) is used to calculate the amount of pattern displacement at the correction point P1 (step S7′).

In this embodiment, the amount of pattern displacement is derived by inputting the output of the third distribution function F3(x) to a conversion function based on a set of arbitrary parameters not including coordinate information.

Denoting the conversion function by fc(Ai; X) (where Ai represents a set of an arbitrary number of parameters, A1, A2, . . . , An, and X represents an input variable), the amount of pattern displacement, ΔPos(x), at the correction point P1 can be expressed as ΔPos(x)=fc(Ai; F3(x)).

As an example, if fc is a second-order polynomial, the above equation is expressed as

ΔPos(x)=A1+A2·F3(x)+A3·F3(x)·F3(x).

The conversion function fc may be a polynomial of higher order, or a nonlinear function, complex function, hyperfunction and the like.

The aforementioned process from step S3 to step S7′ is performed for all the correction points P to calculate the amount of pattern displacement at respective correction points P. Then, the amount of pattern displacement for all the correction points P is used to calculate correction parameters of the pattern position (step S8).

The correction parameters obtained by the foregoing process are inputted to the lithography system and used to correct the initialization values of charged beam control data. The corrected control data is used for deflection control of the charged beam to perform writing. This enables manufacturing of a photomask with high accuracy in which the pattern displacement due to resist charge-up is eliminated. After pattern writing, development is performed to form the desired pattern on the mask substrate.

Then, this mask is used to perform exposure on a semiconductor wafer with a resist formed thereon so that a pattern image is transferred to the resist. Subsequently, development is performed to pattern the resist, and the resist pattern is used as a mask to perform processes such as etching of a film to be processed. According to this embodiment, the mask pattern accuracy can be enhanced. Consequently, it is possible to increase processing accuracy of the wafer and manufacture products with high quality.

In the above embodiments, for convenience of description, only the x-coordinate is used as the input coordinate, represented by a one-dimensional coordinate system. However, in general, the input coordinates are represented by a two-dimensional coordinate system, and consequently the input value and the output value both take the form of a vector represented as (x, y).

The embodiments of the invention have been described with reference to examples. However, the invention is not limited thereto but can be variously modified within the spirit of the invention.

The invention is not limited to manufacturing of a photomask but is applicable to manufacturing of a reflective mask used for patterning with EUV (extreme ultra violet) light, manufacturing of a template used for patterning by the nano-imprint process, and manufacturing of other lithographic masters. Furthermore, the invention is also applicable to the direct writing process for writing a pattern to a semiconductor wafer directly by a charged beam without using a mask or template.

The charged beam is not limited to the electron beam, but other charged beams such as ion beams can also be used.

1. A photomask having a pattern formed by writing of a charged beam on basis of a charged beam control data, the charged beam control data being produced by:
setting a plurality of correction points in a writing area on pattern data;
performing a simulation of writing with a charged beam on basis of the pattern data to divide the writing area, at time of writing each of the correction points, into a written area of writing been already completed and an unwritten area of writing yet to be performed;
deriving, for each of the correction points, a first charging amount distribution due to a fogging effect around each of the correction points using a subset of the pattern data belonging to the written area;
deriving, for each of the correction points, a second charging amount distribution modified from the first charging amount distribution on basis of an effect by which the charging amount due to the fogging effect is reduced at a position irradiated with the charged beam;
deriving amount of pattern displacement at each of the correction points on basis of the second charging amount distribution; and
deriving correction parameters of pattern position on basis of the amount of pattern displacement.

2. The photomask according to claim 1, wherein the first charging amount distribution is derived by convolution of an irradiation amount distribution function of the charged beam on the writing area with a Gaussian function.

3. The photomask according to claim 1, wherein the amount of pattern displacement is derived by convolution of the second charging amount distribution with a preset conversion function.

4. The photomask according to claim 1, wherein the amount of pattern displacement is derived by using a distribution obtained by differentiating the second charging amount distribution and a preset conversion function.

5. The photomask according to claim 4, wherein the conversion function does not include coordinate information of the writing area.

6. The photomask according to claim 1, wherein the amount of pattern displacement is derived by performing trajectory simulation of the charged beam on basis of the second charging amount distribution.

7. A semiconductor device having a device pattern corresponding to the pattern formed on the photomask, the device pattern being formed using the photomask according to any of claims 1-6.

8. A charged beam writing apparatus, comprising:
an input device used to input writing pattern data;
a processor configured to perform a simulation of writing with a charged beam on basis of the pattern data to divide a writing area, at time of writing each of a plurality of correction points set in the writing area on the pattern data, into a written area of writing been already completed and an unwritten area of writing yet to be performed; to derive, for each of the correction points, a first charging amount distribution due to a fogging effect around each of the correction points using a subset of the pattern data belonging to the written area; to derive, for each of the correction points, a second charging amount distribution modified from the first charging amount distribution on basis of an effect by which the charging amount due to the fogging effect is reduced at a position irradiated with the charged beam; to derive amount of pattern displacement at each of the correction points on basis of the second charging amount distribution; and to derive correction parameters of pattern position on basis of the amount of pattern displacement;
a charged beam source; and
a deflector controllably deflecting a charged beam from the charged beam source on basis of the correction parameters of pattern position.

9. The apparatus according to claim 8, wherein the processor derives the first charging amount distribution by convolution of an irradiation amount distribution function of the charged beam on the writing area with a Gaussian function.

10. The apparatus according to claim 8, wherein the processor derives the amount of pattern displacement by convolution of the second charging amount distribution with a preset conversion function.

11. The apparatus according to claim 8, wherein the processor derives the amount of pattern displacement by using a distribution obtained by differentiating the second charging amount distribution, and a preset conversion function.

12. The apparatus according to claim 11, wherein the conversion function does not include coordinate information of the writing area.

13. The apparatus according to claim 8, wherein the processor derives the amount of pattern displacement by performing trajectory simulation of the charged beam on basis of the second charging amount distribution.
